(19) United States
(12) Patent Application Publication
(10) Pub. No.: US 2009/0315584 A1
(43) Pub. Date: Dec. 24, 2009

(54) MEASURING BOARD FOR EXAMINING DIFFERENT TYPES OF SECTIONS OF MCP PRODUCT

(75) Inventor: Kiyomi NAGANUMA, Tokyo (JP)

Correspondence Address: YOUNG & THOMPSON, 209 Madison Street, Suite 500, Alexandria, VA, 22314, US

(73) Assignee: ELPIDA MEMORY, INC., TOKYO (JP)

(21) Appl. No.: 12/488,026

(22) Filed: Jun. 19, 2009

(30) Foreign Application Priority Data
Jun. 20, 2008 (JP) 2008-162264

(51) Int. Cl. G01R 31/26

(52) U.S. Cl. 324/765

(57) ABSTRACT

A measuring board includes: a first memory section measuring socket having a first memory section measuring socket terminal, the first memory section measuring socket terminal being connected to a first memory section terminal of a first memory section of an MCP product; and a second memory section measuring socket having a second memory section measuring socket terminal, the second memory section measuring socket terminal being connected to a second memory section terminal of a second memory section of the MCP product, and the second memory section measuring socket terminal is connected to the first memory section measuring socket terminal.

### BACKGROUND OF THE INVENTION

1. Field of the Invention

The present invention relates to a measuring board for examining different types of sections of MCP products.

Priority is claimed on Japanese Patent Application No. 2008-162264 filed Jun. 20, 2008, the content of which is incorporated herein by reference.

2. Description of Related Art

In recent years, semiconductor devices have been equipped in many electronic products, and have been used as core components. The functionalities of a semiconductor device have become more complex, and a variety of functionalities are now equipped on a single chip. Under such circumstances, in methods for evaluating the characteristics of semiconductor devices, it is important to perform a characteristic evaluation as effectively as possible at the lowest possible cost, for reducing the cost of a semiconductor device itself and for determining strategic advantages of the semiconductor device.

Japanese Unexamined Patent Application, First Publication No. H07-092232 (hereinafter referred to as Patent Document 1) discloses a test board for measuring the electrical characteristic of an integrated circuit (IC). Socket boards are prepared to correspond to required types and they are replaced when handling different types of IC chips, and the shared portion of this test board is used as they are.

Such a method, in which the socket board is individually prepared as the object of replacement corresponding to product types, has already become a standard method in memory testing.

However, in memory testing devices, multi-chip simultaneous measurement is currently prevailing, and the maximum number (the number of sockets) is determined based on a standard of I/O ×4/×8/×16 configuration. A supplying device called a handler to be connected to a tester is also made capable of processing this maximum number, and the physical socket position is preliminarily determined.

In a case where the method disclosed in Patent Document 1 is used in such a device that performs simultaneous measurement on a number of memories, it is difficult to design substrate connections, and therefore there is almost no cost-suppressing effect.

Japanese Unexamined Patent Application, First Publication No. 2006-017527 discloses an automatic testing apparatus for semiconductor devices, a conveyer, and a test board. This test board has a different socket cover for each type of the semiconductor device, a socket main body for arranging the socket cover thereon, and a shared socket substrate section in which the socket main body is mounted.

On this socket substrate section, there is preliminarily mounted a large sized socket main body having numerous pins. By changing the installation position of this socket main body, overall sharing is done. However, in the case of simultaneously measuring multiple chips, it is difficult, with the handler, to control differences in the socket arrangement. Moreover, it is necessary to increase the number of terminals and it is not possible to make effective use of the socket substrate surface. Consequently, the cost for manufacturing the sockets will be deteriorated. Furthermore, in a case of changing the type of the semiconductor device, it is necessary to replace the positioning socket cover and this would not reduce TAT (turn around time).

Japanese Unexamined Patent Application, First Publication No. 2004-158351 discloses a socket board for testing IC devices. It discloses that by forming patterns corresponding to the terminal arrangement of an IC device on the front and back surfaces of the socket board, and switching the front and back surfaces for different types of devices, it is possible to share the socket board.

Japanese Unexamined Patent Application, First Publication No. H10-270495 discloses a semiconductor device, and describes that by bypassing an inner lead within the opening of a base film in a tape carrier, it is possible to share an external circuit substrate.

However, the effect of reducing manufacturing cost is low in both methods.

An MCP (multi-chip package) product has different types of memory sections such as DRAM and FLASH memory on a single chip as a semiconductor device. In evaluating the characteristic of an MCP product, there has been a problem in that two types of measurements for the DRAM and FLASH memory are required, and consequently the manufacturing cost further increases.

The DRAM portion of an MCP product or the like is I/O ×32 in most cases. Due to the restrictions on tester PIN allocation, the number of measurements that can be performed at the same time is half the number of mountable sockets. The PINs on the tester side are all used up, however, the number of the sockets becomes half and there will be created a gap in the socket installation area. The same applies to the FLASH memory portion of an MCP product or the like. If DRAMs and FLASH memories are separately connected at the same time for the purpose of sharing the measuring board, the number of simultaneous measurements will need to be further reduced to half.

FIG. 11A to FIG. 11C respectively show an example of an arrangement of the sockets on the measuring board in a case where the maximum number of the sockets is assumed to be 16 under these restrictive conditions. FIG. 11A shows a case where the maximum number of sockets is 16. FIG. 11B shows a case where there are eight DRAM-dedicated sockets. FIG. 11C shows a case where there are eight FLASH-dedicated sockets. In FIG. 11A to 11C, portions that are marked in black denote sockets in which devices are to be mounted

As shown in FIG. 11A, in a case where the number of PINs of the device is small and the number of PINs of the tester is not restricted, the number of sockets becomes the maximum number that can be processed by the handler.

As shown in FIG. 11B and FIG. 11C, in the case of the MCP product, the number of PINs of I/O that can be connected is preliminarily determined due to the tester side restrictions. For a DRAM, which has a large number of I/O, the number of sockets is reduced to half and becomes 8, even on a device capable of arranging 16 chips for example. That is to say, on the measuring board with eight DRAM dedicated sockets and the measuring board with eight FLASH dedicated sockets, the number of simultaneous measurements is limited to eight. The MCP product is characterized in that the number of PINs of I/O is large, and the number of simultaneous measurements is consequently reduced to half.

As shown in FIG. 11B, on a board dedicated for measuring the DRAM side, the tester is in a state where I/O PINs have all been allocated, and a connection to the FLASH side of the device cannot be established. Consequently, when measuring the FLASH side, it is necessary to prepare a measuring board connected to the FLASH side I/O with another jig shown in FIG. 11C.

Thus, in the case of testing an MCP product, two types of measuring boards for DRAMs and FLASH memories are required due to the tester pin allocation restrictions, and measurement needs to be performed with 2 passes. Consequently an even larger amount of investment is required. Furthermore, MCP products tend to be produced in various types and in a small amount. Therefore the amount of investment tends to become even larger.

In consideration of such circumstances, there has been developed an identical measuring board in which both the DRAM element and the FLASH memory are connected for each socket for mounting the MCP product therein. However, in this identical measuring board, the number of sockets is reduced to half and the productivity is reduced to half. Consequently, the manufacturing process becomes degraded.

If the connection of the DRAM and FLASH memory is connected in series simply in a single device, and it is possible to perform electrical ON/OFF controls for the DRAM and FLASH memory, then eight measurements are possible with the same jig. However, the VIH (voltage input high) limitation of an input terminal is determined by the power supply voltage. Consequently shared signals may lead to a breakage and it is difficult to control measuring boards with different power supply voltages.

### SUMMARY

In one embodiment, there is provided a measuring board which includes: a first memory section measuring socket having a first memory section measuring socket terminal, the first memory section measuring socket terminal being connected to a first memory section terminal of a first memory section of an MCP product; and a second memory section measuring socket having a second memory section measuring socket terminal, the second memory section measuring socket terminal being connected to a second memory section terminal of a second memory section of the MCP product, and the second memory section measuring socket terminal is connected to the first memory section measuring socket terminal.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a perspective view showing an example a measuring board for examining different types of sections of an MCP product according to a first embodiment of the present invention, arranged on a test head (tester);

FIG. 2 is a view showing an example of a connection between the test head (tester), and a first memory section measuring socket and a second memory section measuring socket provided on the measuring board for examining different types of sections of an MCP product according to the first embodiment of the present invention;

FIG. 3 is a plan view of the measuring board for examining different types of sections of an MCP product according to the first embodiment of the present invention, showing an example of an arrangement of the first memory section measuring sockets and the second memory section measuring sockets;

FIG. 4A is a schematic plan view showing an example of an MCP product;

FIG. 4B is a schematic sectional view taken along the line A-A′ of FIG. 4A;

FIG. 5A is a plan view showing an example of connections between the first memory section measuring socket and the second memory section measuring socket provided in the measuring board for examining different types of sections of an MCP product according to the first embodiment of the present invention;

FIG. 5B is a sectional view taken along the line B-B′ of FIG. 5A;

FIG. 6A is a sectional view showing an example of a case where an MCP product is housed in the first memory section measuring socket shown in FIG. 5A;

FIG. 6B is a sectional view showing an example of a case where an MCP product is housed in the second memory section measuring socket shown in FIG. 5A;

FIG. 7A to FIG. 7D are plan views of the measuring board for examining different types of sections of an MCP product according to the first embodiment of the present invention, respectively showing other examples of an arrangement of the first memory section measuring sockets and the second memory section measuring sockets;

FIG. 8 is a schematic plan view showing an example of an arrangement of DRAM measuring sockets and FLASH memory measuring sockets in the measuring board for examining different types of sections of an MCP product according to the first embodiment of the present invention;

FIG. 9 is a schematic plan view showing an example of an arrangement of DRAM terminals and FLASH terminals of an MCP product;

FIG. 10 is an enlarged schematic plan view showing an example of a connection between DRAM measuring sockets and FLASH memory measuring sockets in the measuring board for examining different types of sections of an MCP product according to the first embodiment of the present invention; and

FIG. 11A to FIG. 11C are views respectively showing an example of an arrangement of sockets on a measuring board in a case where the maximum number of the sockets is assumed to be 16.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

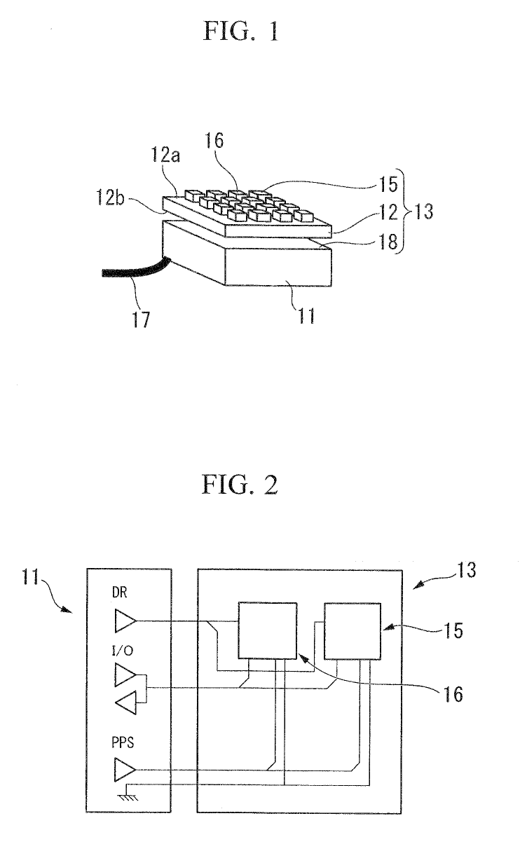

FIG. 1 is a perspective view showing an example a measuring board for examining different types of sections of an MCP product according to a first embodiment of the present invention, arranged on a test head (tester).

As shown in FIG. 1, the measuring board for examining different types of sections of an MCP 13 (hereinafter sometimes simply referred to as measuring board 13) according to the present embodiment includes a substantially rectangular-shaped board substrate 12, and substantially rectangular-shaped first memory section measuring sockets 15 and second memory section measuring sockets 16 arranged in a grid array on one surface 12a of the board substrate 12. Each of these first memory section measuring sockets 15 and the second memory section measuring sockets 16 is configured so as to house an MCP product therein. MCP is an abbreviation for multi-chip package.

On another surface 12b of the board substrate 12, there is arranged, via a connector 18, a test head 11. A cable 17 is connected to the test head 11. The electrical characteristic of DRAMs and FLASH memories of the MCP products are examined by the following methods. DRAMs and FLASH memories of the MCP products are housed in the first memory section measuring socket 15 and the second memory section measuring socket 16. By means of a control section (not shown in the figure), electrical signals are transmitted to or receive from the test head 11, and then, these electrical signals are transmitted to or received from the measuring board 13 via the connector 18. Consequently, the electrical characteristics of DRAMs and FLASH memories of the MCP products can be examined. A DRAM is one type of the volatile memories, and is an abbreviation for dynamic random access memory. A FLASH memory is one type of the nonvolatile memories.

FIG. 2 is a view showing an example of a connection between the test head (tester) 11, and the first memory section measuring socket 15 and the second memory section measuring socket 16 provided on the measuring board 13 according to the first embodiment of the present invention. For sake of simplicity, some sockets are omitted from FIG. 2, and there are shown only one of first memory section measuring sockets 15 and one of the second memory section measuring sockets 16.

As shown in FIG. 2, the test head (tester) 11 has three circuits, a DR circuit to supply command/address signals as DR (driver) signals, an I/O circuit to supply data to the first memory section measuring socket 15 and the second memory section measuring socket 16 and to receive data from the first memory section measuring socket 15 or the second memory section measuring socket 16 as an I/O signal, and a PPS circuit to activate the first memory section measuring socket 15 or the second memory section measuring socket 16. Electrical signals from the DR and I/O are transmitted to the first memory section measuring socket 15 and the second memory section measuring socket 16, and an electrical signal from the PPS (power supply) activates exclusively the first memory section measuring socket 15 and the second memory section measuring socket 16, and the I/O receives an electrical signal of the result of a test performed on an MCP product housed in the first memory section measuring socket 15 or in the second memory section measuring socket 16.

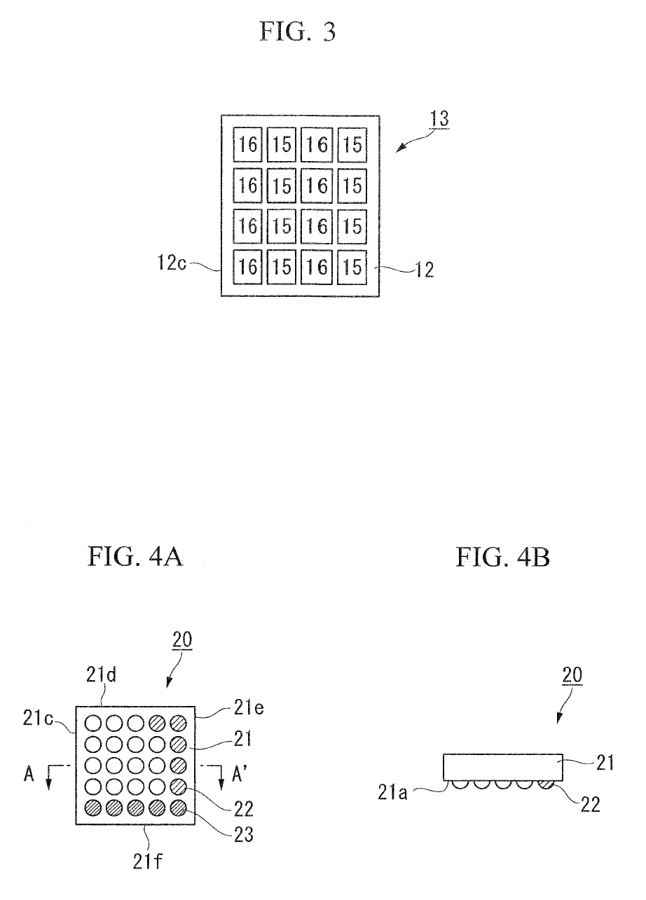

FIG. 3 is a plan view of the measuring board 13 according to the first embodiment of the present invention, showing an example of an arrangement of the first memory section measuring sockets 15 and the second memory section measuring sockets 16.

As shown in FIG. 3, the measuring board 13 according to the present embodiment includes the substantially rectangular-shaped board substrate 12, and the first memory section measuring sockets 15 and the second memory section measuring sockets 16 arranged in a grid array on the one surface 12a of the board substrate 12.

FIG. 3 shows a case where the second memory section measuring sockets 16 are installed in empty areas on the measuring board provided with the first memory section measuring sockets 15. Sockets for measuring memory sections of different types are normally provided on a separate measuring board. In the present embodiment, these sockets are arranged in mutually empty areas, and the connection therebetween is established in parallel. By installing MCP products only in either type of the sockets on a single measuring board, it becomes possible to test each of different types of memory sections of the MCP products. This parallel connection is formed in series in reality as described later.

There are arranged, in a line, first four of the second memory section measuring sockets 16 so as to be parallel with one side 12c of the board substrate 12. There are arranged first four of the first memory section measuring sockets 15 so as to be parallel with the line of the first four of the second memory section measuring sockets 16. Furthermore, there are arranged second four of the second memory section measuring sockets 16 so as to be parallel with the line of the first four of the first memory section measuring sockets 15. Lastly, there are arranged second four of the first memory section measuring sockets 15 so as to be parallel with the line of the second four of the second memory section measuring sockets 16.

The first memory section measuring sockets 15 and the second memory section measuring sockets 16 are preferably arranged so as to be adjacent to each other in this way. As described later, there is a connection between the first memory section measuring sockets 15 and the second memory section measuring sockets 16 arranged adjacent to each other. The distance of this connection is minimized, and it is thereby possible to reduce deterioration in electrical signals to be transmitted or received through the connection.

FIG. 4A is a schematic plan view showing an example of an MCP product. FIG. 4B is a schematic sectional view taken along the line A-A′ of FIG. 4A.

As shown in FIG. 4A and FIG. 4B, an MCP product 20 has a product main body substrate 21, first memory section terminals 22, and second memory section terminals 23. The first memory section terminals 22 and the second memory section terminals 23 respectively have signals drawn out therefrom. The product main body substrate 21 has a substantially rectangular-shape.

As shown in FIG. 4A, on a surface of the product main body substrate 21 of the MCP product 20, there are terminals formed in a 5 by 5 grid array. Among these terminals, a line of the terminals on the side of one side 21f are the second memory section terminals 23. Four of the terminals on the side of another side 21e and one of the terminals on the side of another side 21d, are the first memory section terminals 22.

As shown in FIG. 4B, the MCP product 20 has the first memory section terminals 22 on one surface 21a of the product main body substrate 21.

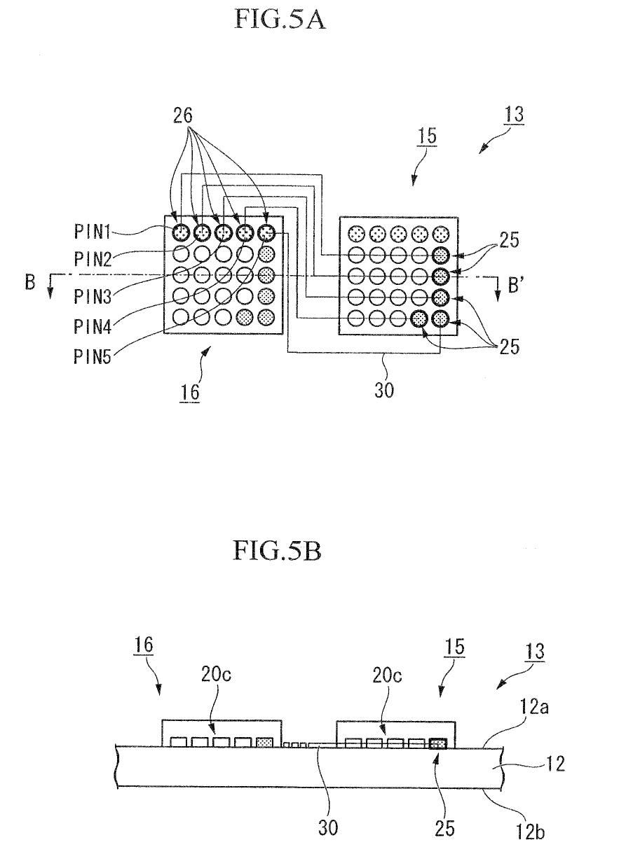

FIG. 5A is a plan view showing an example of connections between the first memory section measuring socket 15 and the second memory section measuring socket 16 shown in FIG. 3. FIG. 5B is a sectional view taken along the line B-B′ of FIG. 5A.

As shown in FIG. 5A, on the first memory section measuring socket 15 there is provided five first memory section measuring socket terminals 25. Moreover, on the second memory section measuring socket 16 there is provided five second memory section measuring socket terminals 26.

The five first memory section measuring socket terminals 25 are respectively crossover-connected in series to the five second memory section measuring socket terminals 26 via wirings 30.

As shown in FIG. 5A, in order to connect the first memory section measuring socket terminals 25 and the second memory section measuring socket terminals 26 that are physically distanced from each other, there are connection methods available including: a two-branch method in which each connection is equally distanced from a tester pin; and a crossover series connection. In a case of using the two-branch method with equal distance connections, if MCP products are mounted only on one side, there will be problem of deterioration in waveforms associated with reflection from the side on which the MCP products are not mounted. Consequently, it is not used.

To the five second memory section measuring socket terminals 26, there are respectively connected five tester pins PIN 1 to 5 of the test head (tester) 11.

In other words, each of the wirings 30 has a first end and a second end. The first ends of the wirings 30 are connected to the first memory section measuring socket terminals 25, respectively. The second ends of the wirings 30 are connected to the second memory section measuring socket terminals 26, respectively. Moreover, the second memory section measuring socket terminals 26 are connected to the tester pins PIN 1 to 5 of the test head (tester) 11, respectively.

As shown in FIG. 5A, the five tester pins PIN 1 to 5 of the test head (tester) 11 are connected to the five second memory section measuring socket terminals 26. The five tester pins PIN 1 to 5 are respectively connected, via wirings 30, to the five first memory section measuring socket terminals 25 in a single continuous line. With this configuration, a PIN resource on the test head (tester) 11 can be shared between a first memory section and a second memory section, and it is possible to make effective use of empty socket positions which are originally empty because the number of sockets which can be arranged on the one surface 12a of the substrate main body 12 are reduced to half due to a I/O ×32 configuration.

As shown in FIG. 5B, the first memory section measuring socket 15 and the second memory section measuring socket 16 are formed on the one surface 12a of the substrate main body 12. The first memory section measuring socket 15 and the second memory section measuring socket 16 are each provided with a housing region 20c for housing the MCP product 20. The housing region 20c can house the MCP product 20.

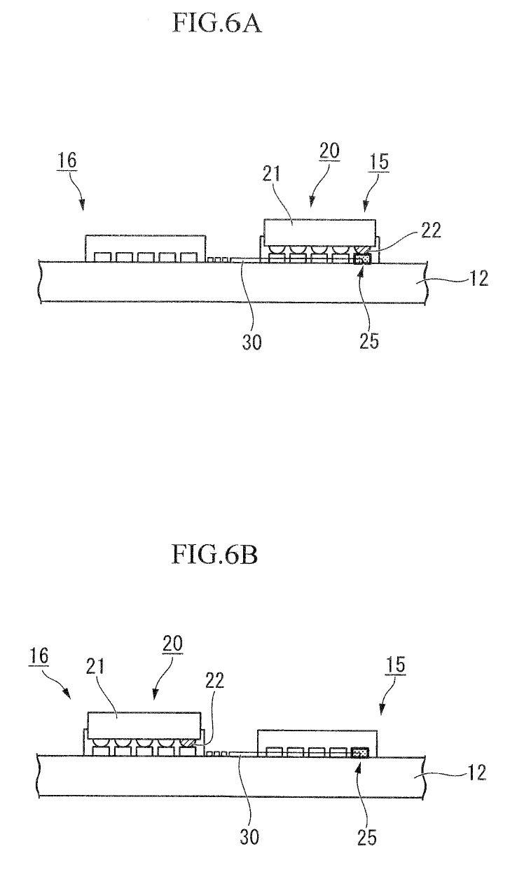

FIG. 6A is a sectional view showing an example of a case where the MCP product 20 is housed in the first memory section measuring socket 15. FIG. 6B is a sectional view showing an example of a case where the MCP product 20 is housed in the second memory section measuring socket 16.

When measuring with use of the measuring board 13 according to the first embodiment of the present invention, there is a prerequisite that the first memory section and the second memory section are not to be measured at the same time. Consequently, when measuring the first memory section, the MCP product 20 is installed only in the first memory section measuring socket 15 to perform the measurement. On the other hand, when measuring the second memory section, the MCP product 20 is installed only in the second memory section measuring socket 16 to perform the measurement. Housing and removal of the MCP product 20 is performed with use of a carrier device called a handler.

By using the measuring board 13 according to the present embodiment, the measuring board for the first memory section and the measuring board for the second memory section no longer need to be replaced, and it is possible to reduce TAT while improving productivity.

Moreover, only the test pins which are required both when measuring the first memory section and the second memory section need to be installed, and therefore, no longer need to install full-pins to examine the MCP products, and productivity can be improved.

As shown FIG. 6A, in a case where the MCP product 20 is housed in the first memory section measuring socket 15, the first memory section terminal 22 is connected to the first memory section measuring socket terminal 25.

Although omitted from FIG. 6A, the four remaining first memory section terminals 22 are respectively connected to the four remaining first memory section measuring socket terminals 25. This is because the number and positions of the first memory section measuring socket terminals 25 are defined so as to respectively correspond to the number and positions of the first memory section terminals 22 of the MCP product 20.

In this state, electrical signals are transmitted to or received from the tester pins PIN 1 to 5 connected to the second memory section measuring socket terminals 26, and it is thereby possible to perform, via the wirings 30, an examination of the electrical characteristic of the first memory section of the MCP product 20.

Similarly, as shown in FIG. 6B, in a case where the MCP product 20 is housed in the second memory section measuring socket 16, although omitted from the figure, the five second memory section terminals 23 are respectively connected to the five second memory section measuring socket terminals 26. This is because the number and positions of the second memory section measuring socket terminals 26 are defined so as to respectively correspond to the number and positions of the second memory section terminals 23 of the MCP product 20.

In this state, electrical signals are transmitted to or received from the tester pins PIN 1 to 5, and it is thereby possible to perform an examination of the electrical characteristic of the second memory section of the MCP product 20.

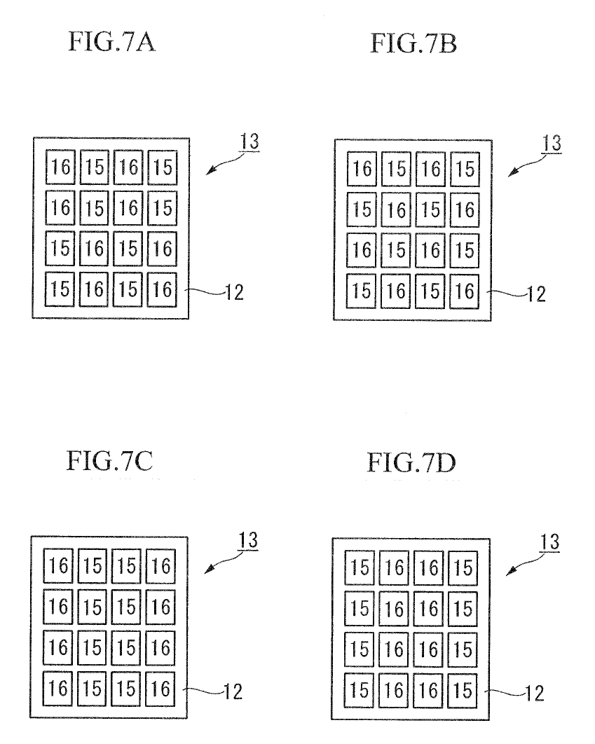

FIG. 7A to FIG. 7D are plan views showing the measuring board 13, respectively showing another example of an arrangement of the first memory section measuring sockets 15 and the second memory section measuring sockets 16. In FIGS. 7A and 7B, two of the first memory section measuring sockets 15 and two of the second memory section measuring sockets 16 are aligned in a direction parallel to one side of the board substrate 12 so that one of the two of second memory section measuring socket 16 is disposed between the two of the first memory section measuring sockets 15, and that one of the two of the first memory section measuring socket 15 is disposed between the two of the second memory section measuring sockets 16. In FIGS. 7C and 7D, four of the first memory section measuring sockets 15 are aligned in a direction parallel to one side of the board substrate 12, and four of the second memory section measuring sockets 16 are aligned in the direction parallel to the same side of the board substrate 12.

Even in the case of being arranged in this way, the first memory section measuring sockets 15 and the second memory section measuring sockets 16 for measuring different types of memory sections, are adjacent to each other. Consequently, it is possible to minimize the connection distance, and thus, it is possible to reduce deterioration in electrical signals. Therefore, the first memory section measuring sockets 15 and the second memory section measuring sockets 16 may be arranged in this way.

The shape of the first memory section measuring socket 15 and the second memory section measuring socket 16 is of a substantially rectangular shape. However, it may be of another shape. The first memory section measuring socket 15 and the second memory section measuring socket 16 may have any shape as long as they have a housing region 20c matching with the outer shape of the MCP product 20, and the MCP product 20 can be housed in the housing region 20c.

The number of the first memory section measuring sockets 15 and the second memory section measuring sockets 16 to be mounted is not particularly limited, and is defined with consideration to differences in the size of the measuring board and the number of simultaneous measurements.

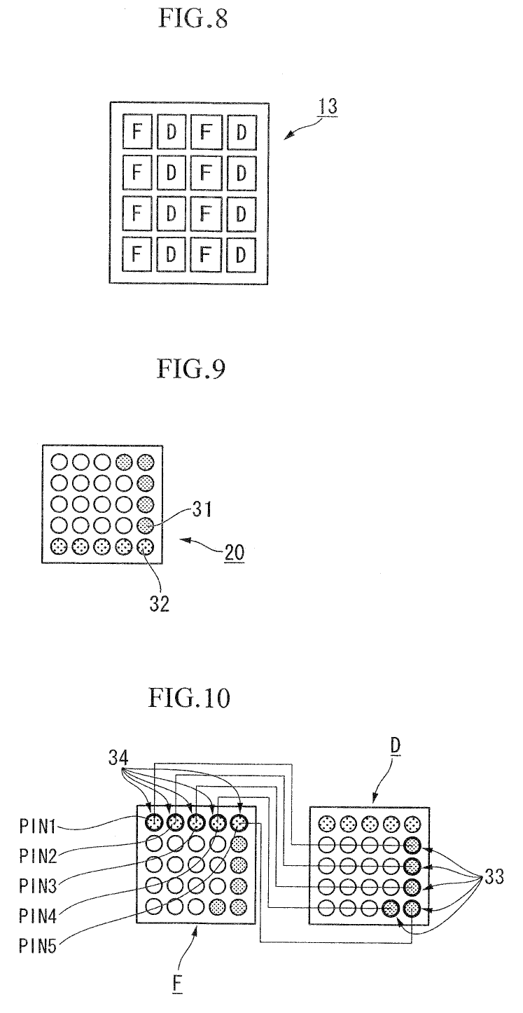

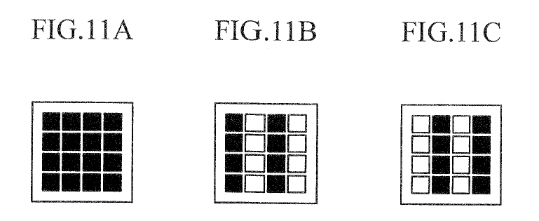

FIG. 8 to FIG. 10 are views for describing a case of the MCP product 20 where the first memory section is a DRAM and the second memory section is a FLASH memory. FIG. 8 is a schematic plan view showing an example of an arrangement of DRAM measuring sockets D and FLASH memory measuring sockets F on the measuring board 13 according to the embodiment of the present invention. FIG. 9 is a schematic plan view showing an example of an arrangement of DRAM terminals and FLASH terminals of an MCP product. FIG. 10 is an enlarged schematic view showing an example of connections between the DRAM measuring socket D and the FLASH memory measuring socket F.

As shown in FIG. 8, the DRAM measuring socket D and the FLASH memory measuring socket F are arranged adjacent to each other.

As shown in FIG. 9, the MCP product 20 is provided with DRAM terminals 31 and FLASH terminals 32.

As shown in FIG. 10, on the FLASH memory measuring socket F, there are provided FLASH memory measuring socket terminals 34 so as, when the MCP product 20 is housed, to correspond to the FLASH terminals 32 of the MCP product 20. The tester pins PIN 1 to 5 are connected to the FLASH memory measuring socket terminals 34. Therefore, the electrical characteristic of the FLASH memory of the MCP product 20 can be measured via the tester pins PIN 1 to 5.

Similarly, on the DRAM measuring socket D, there are provided DRAM measuring socket terminals 33 so as, when the MCP product 20 is housed, to correspond to the DRAM terminals 31 of the MCP product 20. These DRAM measuring socket terminals 33 are connected to the FLASH memory measuring socket terminals 34, and therefore the electrical characteristic of the FLASH memory of the MCP product 20 can be measured via the tester pins PIN 1 to 5.

As described above, in a case where the MCP product has two memory sections of the DRAM and the FLASH memory, it is preferable that the first memory section be the DRAM and the second memory section be the FLASH memory.

Measurement of the electrical characteristic of a DRAM requires high speed testing in which waveform quality is tested most strictly and the influence of waveform degradation due to reflection cannot be ignored. Therefore it is preferable that the DRAM measuring socket terminal in the series connection be arranged on the furthest side. The level of influence associated with the connection distance being lengthened is low.

The FLASH memory measuring socket terminal is arranged partway along the series connection, and waveform precision consequently becomes degraded due to a high level of the influence of waveform degradation associated with reflection. However, it is still within an acceptable range because the FLASH memory is originally a low speed device.

Thus, if the present method is used, it is possible, with a simple connection design and cost of a single measuring board, to measure two types of sections of products. Both of DRAM/FLASH can be measured on a single measuring board.

Since investment need is suppressed, and measurement of both sections of products can be performed by only changing the settings without the need to replace jigs, it becomes possible to reduce switching loss time and therefore, it is possible to reduce TAT.

The measuring board 13 according to the first embodiment of the present invention has the board substrate 12, and the first memory section measuring sockets 15 and the second memory section measuring sockets 16 arranged on the board substrate 12. Since it has this configuration, it is possible to measure two different types of memory sections of MCP products provided with the first memory section and the second memory section. Accordingly, it is possible, with cost of a single measuring board, to measure two different types of memory sections, and development investment can therefore be suppressed. Moreover, since measurement of both sections of products can be performed by only changing the settings, without the need to replace measuring boards, it becomes possible to reduce switching loss time, and therefore, it is possible to reduce TAT.

The measuring board 13 according to the first embodiment of the present invention has the board substrate 12, and the first memory section measuring sockets 15 and the second memory section measuring sockets 16 arranged on the board substrate 12. Since it has this configuration, a PIN resource on the test head (tester) 11 side can be shared between the first memory section and the second memory section, and it is possible to make effective use of empty socket positions which are originally empty because the number of sockets which can be arranged on the one surface 12a of the board substrate 12 are reduced to half due to a I/O ×32 configuration.

The measuring board 13 according to the first embodiment of the present invention has the board substrate 12, and the DRAM measuring sockets 15 and the FLASH memory measuring sockets 16 arranged on the board substrate 12. Since it has this configuration, it is possible to measure two different types of memory sections of MCP products provided with the DRAMs and the FLASH memories. Because two different types of memory sections can be measured with cost of a single measuring board, development investment can be suppressed. Moreover, since measurement of both sections of products can be performed by only changing the settings, without the need to replace measuring boards, it becomes possible to reduce switching loss time, and therefore, it is possible to reduce TAT.

In the measuring board 13 according to the first embodiment of the present invention, the first memory section measuring socket 15 includes the first memory section measuring socket terminals 25 to be connected to the first memory section terminals 22 of the MCP product 20, and the first memory section measuring socket terminals 25 are to be connected to the second memory section measuring socket terminals 26. Since it has this configuration, electrical signals are transmitted to or received from the tester pins PIN 1 to 5 connected to the second memory section measuring socket terminals 26. It is thereby possible to perform, via the wirings 30, an examination of the electrical characteristic of the first memory section of the MCP product 20. Moreover, connection design can be easily done.

In the measuring board 13 according to the first embodiment of the present invention, the second memory section measuring socket 16 includes the second memory section measuring socket terminals 26 to be connected to the second memory section terminals 23 of the MCP product 20. Since it has this configuration, electrical signals are transmitted to or received from the tester pins PIN 1 to 5 connected to the second memory section measuring socket terminals 26. It is thereby possible to perform an examination of the electrical characteristic of the second memory section of the MCP product 20. Moreover, connection design can be easily done.

In the measuring board 13 according to the first embodiment of the present invention, the DRAM measuring socket D includes the DRAM measuring socket terminals 33 to be connected to the DRAM terminals 31 of the MCP product 20, and the DRAM measuring socket terminals 33 are connected to the FLASH memory measuring socket terminals 34. Since it has this configuration, electrical signals are transmitted to or received from the tester pins PIN 1 to 5 connected to the FLASH memory measuring socket terminals 34, and it is thereby possible to perform, via wiring, an examination of the electrical characteristic of the DRAM of the MCP product 20. Moreover, connection design can be easily done.

In the measuring board 13 according to the first embodiment of the present invention, the FLASH memory measuring socket F includes the FLASH memory measuring socket terminals 34 to be connected to the FLASH terminals of the MCP product 20. Since it has this configuration, the tester pins PIN 1 to 5, connected to the FLASH memory measuring socket terminals 34, transmit or receive electronic signals to or from the FLASH terminals 32. It is thereby possible to perform an examination of the electrical characteristic of the FLASH memory of the MCP product 20. Moreover, connection design can be easily done.

In the measuring board 13 according to the first embodiment of the present invention, the first memory section measuring socket 15 is arranged adjacent to the second memory section measuring socket 16. Since it has this configuration, the connection distance from the tester pins PIN 1 to 5 to the first memory section measuring socket terminals 25 are reduced, and it is thereby possible to suppress deterioration in electrical signals. Moreover, connection design can be easily done.

In the measuring board 13 according to the first embodiment of the present invention, the first memory section measuring socket terminals 25 and the second memory section measuring socket terminals 26 are connected to each other, and the tester pins PIN 1 to 5 are connected to the second memory section measuring socket terminals 26. Since it has this configuration, by arranging the MCP product 20 at least in either one of the first memory section measuring socket 15 and the second memory section measuring socket 16, and connecting the tester pins PIN 1 to 5 to the second memory section measuring socket terminals 26, it is possible to examine the electrical characteristic of either one of the first memory section and the second memory section of the MCP product 20.

In the measuring board 13 according to the first embodiment of the present invention, the DRAM measuring socket terminals 33 and the FLASH memory measuring socket terminals 34 are connected to each other, and the tester pins PIN 1 to 5 are connected to the FLASH memory measuring socket terminals 34. Since it has this configuration, by arranging the MCP product 20 at least in either one of the DRAM measuring socket D and the FLASH memory measuring socket F, and connecting the tester pins PIN 1 to 5 to the FLASH memory measuring socket terminals 34, it is possible to examine the electrical characteristic of either one of the DRAMs and the FLASH memories of the MCP product 20.

In the measuring board 13 according to the first embodiment of the present invention, the first memory section measuring socket terminals 25 are arranged on the furthest side in the series connection, and the second memory section measuring socket terminals 26 are arranged partway along the series connection. Since it has this configuration, it is possible, without problems, to perform a measurement of the electrical characteristic of a DRAM in which waveform quality is tested most strictly and the influence of waveform degradation due to reflection cannot be ignored. Moreover, it is possible, without problems, to perform measurement of a FLASH memory, which is originally a low speed device and can accept degradation in waveform precision due to a high level of influence of waveform deterioration associated with reflection.

It is apparent that the present invention is not limited to the above embodiments, but may be modified and changed without departing from the scope and spirit of the invention.

The present invention relates to a measuring board for examining different types of sections of an MCP product, and has applicability in the industries of manufacturing or utilizing semiconductor devices.

What is claimed is:

1. A measuring board comprising:
a first memory section measuring socket having a first memory section measuring socket terminal, the first memory section measuring socket terminal being connected to a first memory section terminal of a first memory section of an MCP product; and
a second memory section measuring socket having a second memory section measuring socket terminal, the second memory section measuring socket terminal being connected to a second memory section terminal of a second memory section of the MCP product,
wherein the second memory section measuring socket terminal is connected to the first memory section measuring socket terminal.

2. The measuring board according to claim 1, wherein the first memory section measuring socket is arranged adjacent to the second memory section measuring socket.

3. The measuring board according to claim 1, wherein the second memory section measuring socket terminal is connected to a tester pin of a tester, and the tester is used for examining electrical characteristics of the first memory section and the second memory section of the MCP product.

4. The measuring board according to claim 1, wherein the first memory section comprises a DRAM, and the second memory section comprises a FLASH memory.

5. The measuring board according to claim 1, wherein the first memory section measuring socket and the second memory section measuring socket house the MCP product.

6. The measuring board according to claim 1, further comprising:
a board substrate,
wherein the first memory section measuring socket and the second memory section measuring socket are provided on the board substrate, so that the first memory section measuring socket and the second memory section measuring socket are adjacent to each other.

7. The measuring board according to claim 1, further comprising:
a wiring having a first end and a second end, the first end connected to the first memory section measuring socket terminal, and the second end connected to the second memory section measuring socket terminal,
wherein the second memory section measuring socket terminal is connected to a tester pin of a tester, and the tester is used for examining the electrical characteristics of the first memory section and the second memory section of the MCP product.

8. The measuring board according to claim 1, further comprising:
a third memory section measuring socket having a third memory section measuring socket terminal;
a fourth memory section measuring socket having a fourth memory section measuring socket terminal, the fourth memory section measuring socket terminal being connected to the third memory section measuring socket terminal; and
a board substrate,
wherein the first, second, third, and fourth memory section measuring sockets are provided on the board substrate, so that the first and second memory section measuring sockets are adjacent to each other, and that the third and fourth memory section measuring sockets are adjacent to each other.

9. The measuring board according to claim 8, wherein the first and third memory section measuring sockets are aligned in a direction parallel to one side of the board substrate, and the second and fourth memory section measuring sockets are aligned in the direction.

10. The measuring board according to claim 8, wherein the first, second, third, and fourth memory section measuring sockets are aligned in the direction parallel to one side of the board substrate, so that the second memory section measuring socket is disposed between the first and third memory section measuring sockets, and the third memory section measuring socket is disposed between the second and fourth memory section measuring sockets.

11. A measuring board comprising:
a first memory section measuring socket having first and second terminals, the first and second terminals connected to first and second terminals of first memory section terminals of a first memory section of an MCP product, respectively;
a second memory section measuring socket having first and second terminals, the first and second terminals connected to first and second terminals of second memory section terminals of a second memory section of the MCP product, respectively,
wherein the first terminal of the first memory section measuring socket is connected to the first terminal of the second memory section measuring socket, and the second terminal of the first memory section measuring socket is connected to the second terminal of the second memory section measuring socket.

12. The measuring board according to claim 11, further comprising:
a board substrate,
wherein the first memory section measuring socket and the second memory section measuring socket are provided on the board substrate, so that the first memory section measuring socket and the second memory section measuring socket are adjacent to each other.

13. The measuring board according to claim 11, further comprising:
first and second wirings, each of the first and second wirings having a first end and a second end, the first end of the first wiring connected to the first terminal of the first memory section measuring socket, the second end of the first wiring connected to the first terminal of the second memory section measuring socket, the first end of the second wiring connected to the second terminal of the first memory section measuring socket, and the second end of the second wiring connected to the second terminal of the second memory section measuring socket,
wherein the first and second terminals of the second memory section measuring socket are connected to first and second tester pins of a tester, respectively, and the tester is used for examining the electrical characteristics of the first memory section and the second memory section of the MCP product.

14. A testing apparatus comprising:
a measuring board having a first memory section measuring socket to connect a first memory section of a semiconductor package and a second memory section measuring socket to connect a second memory section of said semiconductor package, a wiring connected among one of a plurality of first terminals of said first memory section measuring socket, a corresponding one of a plurality of second terminals of said second memory section measuring socket and a test terminal; and
a tester connected to said test terminal and having a power supply circuit to activate a semiconductor package mounted on said first memory section measuring socket without activating a semiconductor package mounted on said second memory section measuring socket in a first memory section measuring mode and to activate a semiconductor package mounted on said second memory section measuring socket without activating a semiconductor package mounted on said first memory section measuring socket in a second memory section measuring mode.

15. The testing apparatus as claimed in claim 14, wherein said tester has an input/output circuit connected to said test terminal.
